(19) United States
(12) Patent Application Publication
(10) Pub. No.: US 2009/0260873 A1
(43) Pub. Date: Oct. 22, 2009

(54) CASING OF ELECTRONIC DEVICE

(75) Inventor: Takaaki Konoma, Kariya-shi (JP)

Correspondence Address: Locke Lord Bissell & Liddell LLP;Attn: IP Docketing, Three World Financial Center, New York, NY, 10281-2101, US

(73) Assignee: KABUSHIKI KAISHA TOYOTA JIDOSHOKKI, Aichi (JP)

(21) Appl. No.: 12/421,999

(22) Filed: Apr. 10, 2009

(30) Foreign Application Priority Data
Apr. 16, 2008 (JP) 2008-106970

(51) Int. Cl. H05K 7/20; H05K 7/00

(52) U.S. Cl. 174/548; 174/559

(57) ABSTRACT

A casing of an electronic device has a base member, a cover, a bracket and a fastener. The base member made of a bent metal plate has a base and at least three base side walls extending upward from sides of the base. The cover is made of a bent metal plate that is thinner than that of the base member and has a top and at least three cover side walls extending downward from sides of the top. Lower parts of two opposed cover side walls and two opposed base side walls are overlapped with each other thereby to form overlapped portions. The bracket is fixed by the fastener to the base side wall and the cover side wall at the overlapped portion. At least one end portion of the base side wall to which the bracket is fixed and one end portion of the adjacent base side wall are overlapped and connected with each other thereby to form an overlapped end portion.

### BACKGROUND OF THE INVENTION

The present invention relates generally to a casing of an electronic device and, more specifically, to a casing of an electronic device which is fixed to an object, such as a vehicle, through a bracket by a fastener.

An electronic device such as an inverter for a vehicle has a casing in which a circuit board having various kinds of electronic components mounted thereon and a heat sink radiating heat generated from the electronic components are cased. Generally a box-shaped case which is divided into two parts, i.e. a base member and a cover member, is used as the casing of the electronic device. The electronic device is fixed to a specified position, e.g., of a vehicle through a bracket which is fixed to the casing. As an example of such the casing of an electronic device, a unit case designed to lower the cost and to reduce the weight is disclosed in Japanese Patent Application Publication NO. 2002-335084.

The unit case disclosed in the above reference will be described with reference to FIG.5. The unit case includes a casing 60 formed by cutting and bending a plate and a metal base member 70 mounted to the bottom of the casing 60 so as to close the bottom. The casing 60 and the base member 70 are fixed together by self-tapping screws 61. The casing 60 is formed by bending an aluminum alloy plate into a box-shape with an opening at the bottom thereof. Any two adjacent sides of the casing 60 overlap each other at positions adjacent to four corners of the casing 60 thereby to form overlapped portions 62A through 62D. The overlapped portions 62A through 62D are formed therethrough with tongue-shaped mounting tabs 63A through 63D, respectively each having therethrough a hole. A circuit board 50 is fixed to the casing 60 by self-tapping screws 51 inserted through holes 50A of the circuit board 50 and through the holes of the mounting tabs 63A through 63D. The base member 70 has at the four sides thereof upstanding portions 71 formed by bending. Two upstanding portions 71 on two opposite sides thereof corresponding to the overlapped portions 62A through 62D of the casing 60 are formed with mounting tabs 73A through 73D so as to extend upward inside the overlapped portions 62A through 62D when the base member 70 is assembled to the casing 60. Each of the mounting tabs 73A through 73D is formed therethrough with a hole. The casing 60 is fixed to the base member 70 by the self-tapping screws 61 screwed through the holes of the overlapped portions 62A through 62D and the holes of the mounting tabs 73A through 73D. Brackets 74 are fixed by spot welding and the like to the base member 70 at three positions so as to extend outward from the base member 70. Each bracket 74 is formed at a position adjacent to the distal end thereof with a threaded hole for receiving therethrough a bolt 75 for mounting the unit case to the vehicle.

The unit case disclosed in the above reference permits reduction in weight as compared to a unit case made of die-cast aluminum. The plural brackets 74 for mounting the unit case to the vehicle are fixed to the base member 70 by welding. The strength of supporting the bracket 74 depends on the strength of the base member 70, so that the base member 70 needs to be made thick enough to secure the strength. However, the increased thickness of the base member 70 poses limitation on reduction of weight. Fixing the bracket 74 by welding is troublesome as compared to fixing by screws and it is difficult to control the strength of fixing by welding. Furthermore, when the object to which the brackets 74 are fixed or the fixing position is changed, it is also difficult to replace the base member 70 or the brackets 74 by any other suitable counterparts.

The present invention which has been made in light of the above problems is directed to providing a casing of an electric device which makes possible reduction of its weight and also to secure sufficient fixing strength of bracket.

### SUMMARY OF THE INVENTION

A casing of an electronic device has a base member, a cover, a bracket and a fastener. The base member made of a bent metal plate has a base and at least three base side walls extending upward from sides of the base. The cover is made of a bent metal plate that is thinner than that of the base member and has a top and at least three cover side walls extending downward from sides of the top. Lower parts of two opposed cover side walls and two opposed base side walls are overlapped with each other thereby to form overlapped portions. The bracket is fixed by the fastener to the base side wall and the cover side wall at the overlapped portion. At least one end portion of the base side wall to which the bracket is fixed and one end portion of the adjacent base side wall are overlapped and connected with each other thereby to form an overlapped end portion.

Other aspects and advantages of the invention will become apparent from the following description, taken in conjunction with the accompanying drawings, illustrating by way of example the principles of the invention.

### BRIEF DESCRIPTION OF THE DRAWINGS

FIG. 1A is a perspective view showing an electronic device having a casing constructed according to a preferred embodiment of the present invention;

FIG. 1B is an exploded perspective view showing the electronic device of FIG. 1A;

FIG. 2 is a perspective view of a base of the casing of FIG. 1;

FIG. 3 is a plan view of the electronic device of FIG. 1;

FIG. 4 is a cross-section of the electronic device as seen from the line I-I of FIG.3; and

FIG. 5 is an exploded perspective view of a casing of an electronic device according to a prior art.

### DETAILED DESCRIPTION OF THE PREFERRED EMBODIMENT

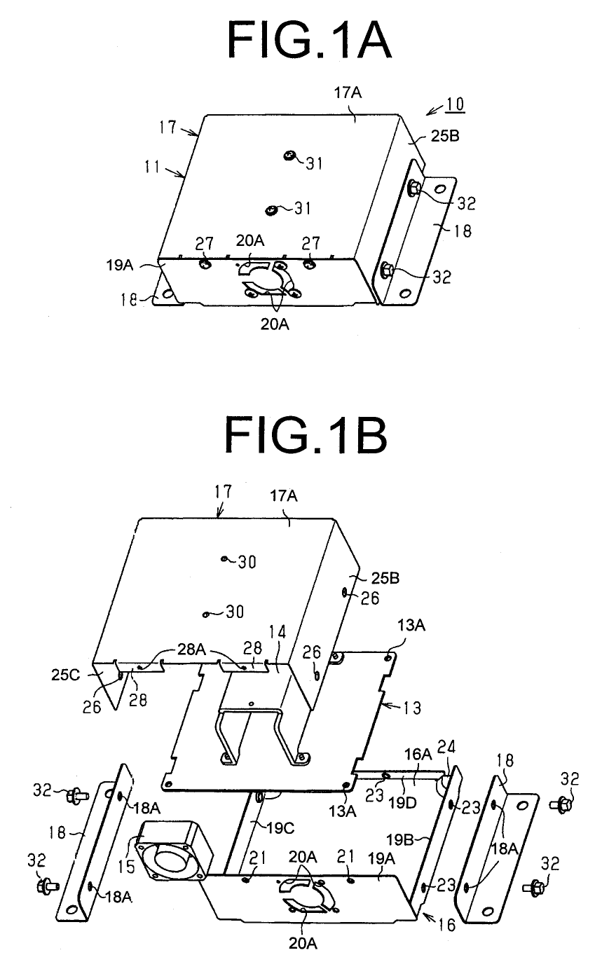

The following will describe the preferred embodiment according to the present invention with reference to FIGS. 1 through 4. Referring to FIGS. 1A and 1B, the electronic device is designated generally by numeral 10 and the casing of the electronic device 10 is designated generally by numeral 11. The casing 11 has therein a circuit board 13 having various electronic parts such as a coil and a capacitor mounted thereon, a heat sink 14 and a fan 15. A printed board is used as the circuit board 13.

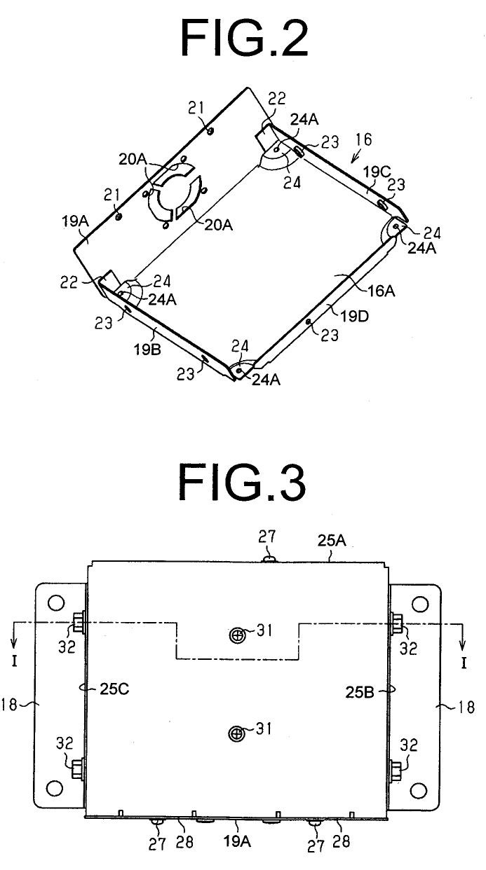

The casing 11 includes a base member 16, a cover member 17 and a pair of brackets 18. The base member 16 is formed by bending a metal plate so as to have four base side walls 19A through 19D extending upward from four sides of a rectangular-shaped base 16A, as shown in FIG. 1B and FIG. 2. One of the base side walls extending longitudinally from the base 16A, i.e. 19A, has a height that is substantially the same as that of the casing 11. Two base side walls 19B and 19C, adjacent to the base side wall 19A are so formed symmetrically and with a height that is lower than that of the bracket 18. The base side wall 19A is formed therethrough with air passage holes 20A and a pair of holes 21 receiving screws 27 for mounting the base side wall 19A to the cover member 17.

Referring to FIG. 2, longitudinal end portions of the base side walls 19B and 19C of the base member 16 adjacent to the base side wall 19A are bent inward and overlap with the base side wall 19A, thereby forming overlapped end portions 22 at opposite end portions of the base side wall 19A. The base side walls 19B and 19C are connected to the base side wall 19A at the overlapped end portions 22. Each of the base side walls 19B and 19C is formed at positions adjacent to the opposite ends thereof with two threaded holes 23 receiving bolts 32 as fasteners for fixing the brackets 18 to the base member 16. In the present embodiment, the threaded hole 23 is formed by tapping after providing an extrusion treatment to the base side walls 19B and 19C.

The base side wall 19D is formed so as to face the base side wall 19A and have a height lower than that of the base side walls 19B and 19C and a length shorter than that of the base side wall 19A so that a clearance is provided between the base side wall 19D and each of the base side walls 19B and 19C. A threaded hole 23 is formed through the base side wall 19D by tapping and providing an extrusion treatment.

As shown in FIG. 2, a seat 24 is provided protruding upward from the upper surface of the base 16A at each of the four corners of the base 16A, serving as the mounting surface for supporting the circuit board 13 in contact with the bottom surface thereof. A hole 24A is formed in each seat 24 and a nut (not shown) is welded to the base member 16 at the position corresponding to each hole 24A on the bottom side of the base member 16 that is opposite from the side to which the circuit board 13 is mounted in contact with the seats 24. The circuit board 13 is fixed to the base 16A by bolts (not shown) inserted through holes 13A formed through the circuit board 13 at four corners thereof and the holes 24A of the seat 24.

The cover member 17, whose surface area is larger than that of the base member 16, is formed by bending a metal plate that is thinner than that of the base member 16 into a box shape having a top 17A and three cover side walls 25A through 25C extending downward from the sides of the top 17A (see FIGS. 1B and 3). To be specific, the cover member 17 is formed in the shape of a square box having one side open. Two opposite cover side walls 25B and 25C extending perpendicularly to the longitudinal direction of the top 17A are formed symmetrically, having a height that is substantially the same as that of the casing 11. The cover member 17 is arranged with its cover side walls 25B and 25C located outward of the base side walls 19B and 19C of the base member 16. The cover side walls 25B and 25C of the cover member 17 are formed therethrough with holes 26 at positions facing the threaded holes 23 of the base member 16 when the cover member 17 is mounted to the base member 16.

The cover side wall 25A of the cover member 17 facing the base side wall 19D of the base member 16 is formed with a height that is substantially the same as that of the casing 11. A hole (not shown) is formed through the cover side wall 25A at the position facing the thread hole 23 of the base side wall 19D of the base member 16. The cover member 17 is arranged with lower portion of the cover side wall 25A located outward of the base side wall 19D of the base member 16 and the cover side wall 25A is fixed to the base side wall 19D by a screw 27 inserted from outside, as shown in FIG. 3.

The top 17A of the cover has a pair of tabs 28 formed by bending downward part of the top 17A so as to face upper part of the base side wall 19A of the base member 16. A hole 28A is formed through each tab 28 and a nut (not shown) is welded to the tab 28 on the inner side thereof at the position corresponding to the hole 28A. With the tabs 28 of the cover member 17 located inward of the base side wall 19A of the base member 16, the base side wall 19A is fixed to the tabs 28 by screws 27 inserted through the holes 21, 28A and the nuts from outside, as shown in FIG. 1A and FIG. 3.

Two holes 30 are formed through the top 17A of the cover member 17 so as to face the heat sink 14. The cover member 17 is fixed to the heat sink 14 by screws 31 with the top 17A in contact with the heat sink 14.

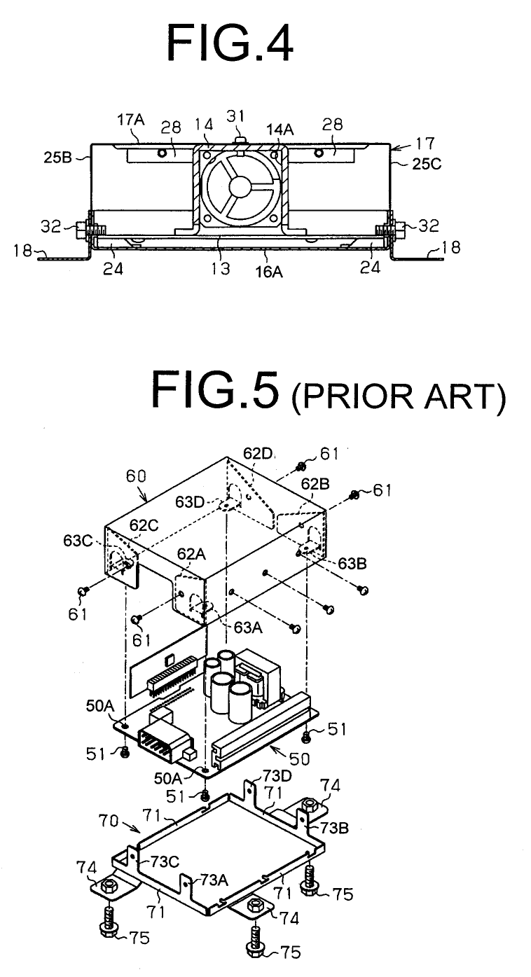

The brackets 18 fixing the casing 11 to a specified position, for example, of a vehicle have a portion facing the base side walls 19B, 19C, and a portion facing the vehicle body. The bracket 18 is formed in an L-shape in cross-section in the present preferred embodiment. The portion of each bracket 18 facing the base side walls 19B, 19C of the base member 16 has a length (length in vertical direction in FIG. 3) that is substantially the same as that of the base side walls 19B, 19C and a height that is greater than that of the base side walls 19B, 19C. Two holes 18A are formed through each bracket 18 at the positions corresponding to the threaded holes 23 of the base side walls 19B and 19C. The base member 16 is fixed to the bracket 18 with the base 16A of the base member 16 set above the horizontal portion of the brackets 18, as shown in FIG. 4. To be more specific, the bolts 32 as a fastener are inserted through the holes 18A of the brackets 18 and the holes 26 of the cover side walls 25B, 25C of the cover member 17 and screwed into the threaded holes 23 of the base side walls 19B, 19C of the base member 16 with the cover side walls 25B, 25C located outward of the base side walls 19B, 19C and the brackets 18 located outward of the cover side walls 25B, 25C. Namely, the bolts 32 function to fix the brackets 18 to the casing 11 and to fix the cover member 17 to the base member 16 as well.

The heat sink 14 is so arranged that one end of air passage 14A of the heat sink 14 faces the fan 15, and the heat sink 14 is fixed to the circuit board 13 by bolts, as shown in FIG. 4. The heat sink 14 functions to radiate the heat generated by the electronic components mounted on the circuit board 13 and also to support the cover 17 on the upper surface thereof.

Although the base member 16 is arranged to be located at the bottom of the electronic device 10 in the preferred embodiment, the base member 16 may be arranged in such a way that the bottom wall thereof extends vertically or is inclined.

The following will describe the operation of the electronic device 10 as constructed above. As stated earlier, the electronic device 10 of the present preferred embodiment is fixed to a specified position of a vehicle by bolts. When connected to a power source, the electronic device 10 is set in operable state. When the electronic device 10 is driven, the fan 15 is also driven and cools the electronic components. When the fan 15 is driven, air is drawn into the casing 11 through the air passage holes 20A facing the fan 15 and then blown toward the air passage 14A of the heat sink 14. The air thus blown moves through the air passage 14A and flows out of the casing 11 through an exhaust hole (not shown) formed in facing relation to the air passage hole 20A.

The following advantageous effects are obtained according to the preferred embodiment.
(1) The casing 11 of the electronic device 10 is formed by fixing the base member 16 and the cover member 17 together, both of which are made of a bent metal plate, by the bolt 32. The base member 16 has base side walls 19A through 19D extending upward from the sides of the base 16A. The cover 17 is formed by bending a metal plate thinner than that of the base member 16 and has three cover side walls 25A through 25C extending downward from the sides of the top 17A. The brackets 18 are fixed to the base member 16 and the cover member 17 at the positions thereof where the base member 16 and the cover member 17 overlap each other. Specifically, the brackets 18 are fixed by the bolts 32 to two base side walls 19B and 19C of the base member 16 and two cover side walls 25B and 25C of the cover member 17. Thus, the bolt 32 functions to fix the brackets 18 to the base side walls 19B and 19C of the base member 16 and the cover side walls 25B and 25C of the cover member 17, respectively, and also to fix the cover member 17 to the base member 16. Therefore, time-consuming operation for fixing can be facilitated and the number of parts to be used for the casing 11 can be reduced. The strength of the parts of the casing 11 to which the brackets 18 are fixed is secured by overlapping the base member 16 and the cover member 17 at the lower part of the cover side walls 25B and 25C of the cover member 17 and the base side walls 19B and 19C of the base member 16, respectively. Moreover, the cover member 17 whose surface area is greater than that of the base member 16, is made of a metal plate with a thickness that is smaller than that of the base member 16. Therefore, the casing 11 can be made light in weight, as compared to a case where the thickness of the cover 17 is greater than that of the base member 16, with the result that the sufficient strength of the part of the casing 11 to which the brackets 18 are fixed can be obtained while achieving the weight reduction of the casing 11.
(2) Two opposed base side walls 19B and 19C of the base member 16 to which the brackets 18 are fixed are connected at end portions thereof to the base side wall 19A of the base member 16 by way of the overlapped end portions 22. Therefore, the strength of the base side walls 19B and 19C to which the brackets 18 are fixed and the base side wall 19A as well of the base member 16 is increased, as compared to a case where the base side walls 19A through 19C are provided independently without being connected.
(3) The brackets 18 are formed so as to extend along the overlapped portions of the base side walls 19B and 19C of the base member 16 and the cover side walls 25B and 25C of the cover member 17 extending in facing relation to each other. Therefore, the bracket 18 serves to increase the strength of the casing 11, as compared to a case where a plural of shorter brackets are fixed.
(4) The seats 24 are formed on the base 16A at four corners thereof as the mounting surface to which the circuit board 13 is fixed by screws and the heat sink 14 is mounted on the circuit board 13 which is in turn fixed to the seat 24. Therefore, the mounting to which the circuit board 13 is fixed is formed easier as compared to a case where the mounting for the circuit board 13 is formed in the cover 17.
(5) The heat sink 14 is arranged in contact with the top 17A of the cover member 17. Therefore, heat radiation efficiency is increased as compared to a case where the heat sink 14 is spaced apart from the top 17A.
(6) The top 17A of the cover member 17 is fixed to the heat sink 14 by the screws 31. Therefore, the heat sink 14 serves also as a reinforcement for the electronic device 10 used, for example, in a vehicle that is subjected to frequent vibration.
(7) The brackets 18 are fixed to the casing 11 to support the casing 11 in such a way that the base 16A of the base member 16 is located above the horizontal portion of the bracket 18. Therefore, vibration at the position where the electronic device 10 is installed is hardly transmitted to the circuit board 13 through the base 16A, as compared to a structure wherein the bottom surface of the base member 16 of a casing 11 is located at the same level as that of the bracket 18.

The present invention is not limited to the above-described preferred embodiment, but it may be embodied in various ways as exemplified below. The seat 24 for supporting the circuit board 13 may be provided not only at four corners of the base 16A of the base member 16 but also at a position of the base 16A corresponding to the position where the heat sink 14 is mounted. The increased number of the seats 24 for supporting the circuit board 13 helps to restrict the resonant phenomenon of the circuit board 13 and improves the strength of the casing 11. Accordingly, the thickness of the bracket 18 can be made thinner.

The base member 16 may be formed by bending a metal plate so as to have at least three upstanding base side walls extending from the sides of the base 16A. At least one end portion of the base side walls 19B and 19C to which the brackets 18 are fixed may be connected to their adjacent base side wall of the base member 16 through the overlapped end portion such as 22. Alternatively, the base side wall 19D of the base member 16 may be formed with the same length as the base side wall 19A and the overlapped end portion such as 22 may be provided only at the opposite end portions of the base side wall 19D. Alternatively, the overlapped end portion such as 22 may be provided by bending the opposite end portions of the base side wall 19A or 19D and placing the bent end portions over their adjacent end portions of the base side walls 19B and 19C. The base member 16 may have only three base side walls 19A through 19C, dispensing with the base side wall 19D.

The cover member 17 may have at least three cover side walls extending downward from the sides of the top 17A. Alternatively, the cover member 17 may have four cover side walls. At least one of end portion of the cover side walls 25B and 25C, to which the brackets 18 are fixed, may be connected to their adjacent cover side wall 25A through the overlapped portions in the same manner as in the case of the base side walls 19B and 19C of the base member 16.

The relative location between the cover side walls 25B and 25C and the base side walls 19B and 19C, to which the brackets 18 are fixed, is not limited to that of the preferred embodiment wherein the base side walls 19B and 19C of the base member 16 are located inward of the cover side walls 25B and 25C of the cover member 17, but the cover side walls 25B and 25C of the cover member 17 may be located inward of the base side walls 19B and 19C. In this case, the threaded holes 23 to which the brackets 18 are fixed are formed through the cover side walls 25B and 25C of the cover member 17.

The threaded holes 23 to which the brackets 18 are fixed are not necessarily formed by tapping after providing an extrusion treatment, but they may be formed by welding nuts or by caulking (fitting) nuts into holes.

The shape of the bracket 18 is not limited to an L-shaped cross-section, but it may be a step-shaped cross-section, as long as the bracket 18 has portions facing the base side walls 19B and 19C, and an object to which the casing 11 is fixed, respectively. Alternatively, a composite shape comprising both an L-shape and a step-shape in cross-section may be used.

The overlapped end portion 22 may be formed in various ways other than welding, such as riveting and caulking. In other words, the bent plate constituting the overlapped end portions 22 may be bent to form a smaller angle than a right angle and then be connected by caulking.

The cover member 17 may only be set in contact with the heat sink 14 without being fixed thereto by the screws 31. The height of the heat sink 14 may be adjusted so that the heat sink 14 is clear of the top 17A of the cover member 17. However, the structure in which the heat sink 14 is in contact with the cover member 17 is preferable in view of the heat radiation and the strength of the casing 11.

Instead of mounting to the base member 16, the circuit board 13 may be mounted to the cover 17 as in the case of the aforementioned Japanese Patent Application Publication NO. 2002-335084.

Therefore, the present embodiment is to be considered as illustrative and not restrictive, and the invention is not to be limited to the details given herein but may be modified within the scope of the appended claims.

This application claims a foreign priority benefit based on Japanese Patent Application No. 2008-106970, filed on Apr. 16, 2008, which is hereby incorporated by reference herein in its entirety as if fully set forth herein.

What is claimed is:

1. A casing of an electronic device comprising:
a base member that is made of a bent metal plate, and has a base and at least three base side walls extending upward from sides of the base;
a cover that is made of a bent metal plate that is thinner than that of the base member, and has a top and at least three cover side walls extending downward from sides of the top;
a bracket; and
a fastener;
wherein lower parts of two opposed cover side walls and two opposed base side walls are overlapped with each other thereby to form overlapped portions, and the bracket is fixed by the fastener to the base side wall and the cover side wall at the overlapped portion, at least one end portion of the base side wall to which the bracket is fixed and one end portion of the adjacent base side wall are overlapped and connected with each other, thereby to form an overlapped end portion.

2. The casing of an electronic device according to claim 1, wherein the bracket extends along the overlapped portion.

3. The casing of an electronic device according to claim 1, wherein the bracket has a horizontal portion, the base member is fixed to the bracket with the base set above the horizontal portion.

4. The casing of an electronic device according to claim 1, wherein the base has a seat, a circuit board is fixed to the base in contact with the seat and a heat sink is mounted on the circuit board.

5. The casing of an electronic device according to claim 4, wherein the heat sink is arranged in contact with the top of the cover member.

6. The casing of an electronic device according to claim 5, wherein the top of the cover member is fixed to the heat sink.
